(19) United States
(12) Patent Application Publication
(10) Pub. No.: US 2005/0212565 A1
(43) Pub. Date: Sep. 29, 2005

(54) Single-chip digital phase frequency synthesiser

(76) Inventor: John W. Bogdan, Ottawa, ON (CA)

Correspondence Address: John W Bogdan, 1210 Major Street, Ottawa, ON, K2C 2S2, CA

(21) Appl. No.: 10/498,184

(22) PCT Filed: Dec. 2, 2002
(86) PCT No.: PCT/CA02/01873

§ 371 Date: Jun. 7, 2004

(30) Foreign Application Priority Data
Dec. 7, 2001 (CA) 2,364,506

(51) Int. Cl. H03B 21/00

(52) U.S. Cl. 327/105

(57) ABSTRACT

An inexpensive, reliable and high quality digital phase frequency synthesis method and circuit providing universal transmission synchronizer for wireless, optical, or wireline transmission systems and for a wide range of data rates. In particular this invention enables the transmission synchronizer to produce a variety of network element synchronization clocks fulfilling a programmable phase transfer function versus external synchronization clocks. The transmission synchronizer designed in accordance with this invention integrates comprehensive programmable reference monitoring, phase transfer processing, reference switching and protection switching functions into a single integrated circuit; based on high resolution synthesized clock generator, high resolution digital phase detectors, and efficient on chip system architecture.

### BACKGROUND OF THE INVENTION

1. Field of the Invention

This invention is directed to generation of a synchronization clock for a telecommunication system and more particularly to Integrated Timing Systems and Circuits (ITSC) which are used to implement universal transmission synchronizer (UTS).

The ITSC allow the UTS to integrate all digital PLL (DPLL), analog PLL (APLL) and system timing control circuits into a single ASIC solution. The UTS may be used for wireless, optical, or wireline transmission systems and for a wide range of data rates.

2. Background Art

Maintaining accurate timing is critical to the transmission of high speed data via telecommunication networks. Land based, cellular, and satcom networks require precision timing to prevent corruption of the transmitted data.

Timing is derived from external timing devices which are synchronized to a Primary Reference source such as a Cesium Beam Standard. (The element Cesium is extremely stable and can be excited by radio energy to produce a 9.44 GHz reference frequency that is electronically maintained to 1 part in 10E13 stability). The Global Positioning System receives and rebroadcasts a Cesium reference for use by telecommunication systems throughout the world. This same GPS timing signal is used by telecommunication systems or navigation systems.

This primary reference is not always possible. When it is not, alternate sources are used to maintain the performance of the appropriate telecommunication system or navigation system. Some kind of synchronizer is usually used to provide a reference clock to telecommunication equipment. Such synchronizer accepts a primary reference source as one of its inputs. It also accepts a line input such as an optical transmission line.

The synchronizer passes the primary reference source to the network equipment in accordance to a set of performance rules. If the rules are violated, the synchronizer switches to the Line timing source and passes that to the network equipment. The line timing source is generated by a different piece of network equipment which is also synchronized to an external primary reference and therefore should be as accurate as the external input.

The synchronizer has its own clock which is normally synchronized to the External or Line input. The synchronizer clock stores information from the synchronization reference clock.

If the synchronization reference is interrupted, then the synchronizer uses its stored data to maintain the stability of its clock. This is referred as hold-over mode. Once the reference signal is restored the synchronizer will switch back to the reference clock.

If the hold-over clock can not provide the stability required because the stored data is corrupted or some other malfunction, then the synchronizer will switch to free-run mode.

In free-run the accuracy of the timing signal is the basic accuracy of the clock in the synchronizer with no synchronization reference clock.

Current synchronizers use DPLLs for synchronized clock generation. DPLLs allow lowering loop bandwidth in order to comply with the communication standards.

Synchronizer DPLL can be implemented using digital to analog converter (DAC), or direct digital frequency synthesis (DDFS), or direct digital phase synthesis (DDPS).

Current DPLLs typically use microcomputers, EEPROM (electrically erasable programmable read-only memory) and a high resolution DAC (digital phase detector) for controlling the VCXO.

Generally, the use of currently available DACs in DPLL designs necessitates the use of a TCVCXO (temperature compensated voltage controlled crystal oscillator). This special type of oscillator is expensive and must be manufactured with a relatively high frequency of oscillation for providing a telecommunication terminal with a wide range of clock signals derived from the output without having to use additional PLLs. However, this high frequency design makes the oscillator more expensive.

The temperature drift is yet another handicap of DAC-based designs that must be compensated. Also, current DAC phase drift which, as a result, may build up. These limitations demand additional and expensive circuitry for improving the performance of the DPLL.

Other known type of DPLL uses the DDFS method.

The DDFS implies eliminating each n-th pulse in an M-pulses sequence of an incoming digital signal, filtering the resultant signal, eliminating the undesired side bands, and extracting the desired frequency. The circuits based on DDFS are provided with a microcontroller and an EEPROM for determining n, M and effecting the deletion. Also, the DDFS algorithm requires complex logic and long acquisition times. Furthermore, if a low frequency off-shelf oscillator such as for example a temperature compensated crystal oscillator (TCXO) is used in this configuration, an additional analog PLL is necessary for obtaining the desired high frequency by multiplying the frequency of TCXO's fixed reference clock.

Yet another disadvantage of the current DDFS is that the clock has rather high jitters, such that another additional analog PLL is generally used for reducing the jitters.

Still other DPLL implementation can be based on the DDPS method which has been introduced in the U.S. Pat. No. 5,910,753 Bogdan 8 Jun. 1999.

Although DDPS method eliminates the above disadvantages of the DAC and DDFS based solutions and significantly reduces complexity and cost, it still requires external analog amplifiers and VCXO for complete implementation of a transmission synchronizer.

There was a need for a synchronizer and a method of synchronization which will further reduce cost and complexity and allow higher degree of on-chip integration by eliminating the external analog amplifiers and VCXO for a wide variety of telecommunication terminals.

### SUMMARY OF THE INVENTION

Purpose of the Invention

It is an object of present invention to provide a universal synchronizer for use in variety of telecommunication systems based on digital phase frequency synthesis (DPFS). The synchronizer of the invention may be used for wireless, optical, or wireline transmission systems and works well with a wide ranges of data rates. The synchronizer according to the invention may be used for example for SONET line-timing (frame) clock generation, and may be adapted to provide SONET minimum clock (SMC) hold-over and free-run capabilities, as well as external timing clocks generation with Stratum 3 hold-over and free-run capabilities.

It is other object of the present invention to create systems and circuits which allow a complete on-chip integration by eliminating all the external components like DACs, VCXOs, analog PLLs, microcontrollers and EEPROMs.

Still other object of the invention is to create new digital phase detection techniques,
which simplify currently known phase detectors logic and control algorithms of output clock phase, while maintaining performances of leading known solutions like the DDPS.
   DPFS Method

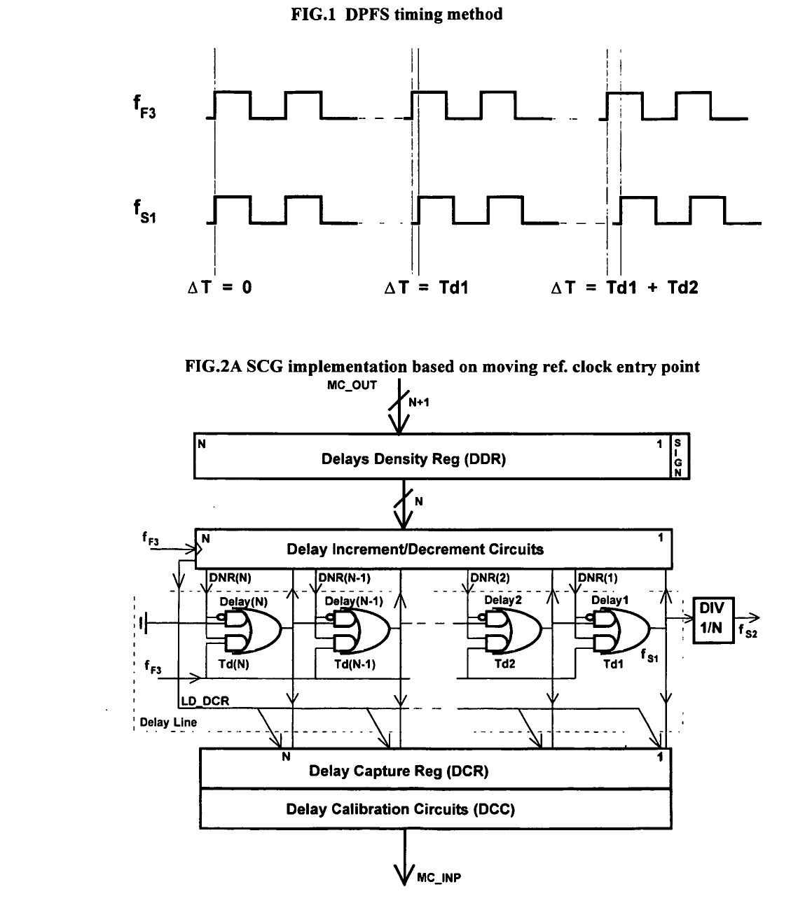

Accordingly the invention provides DPFS (see FIG. 1) as a new timing method for programming and controlling a phase and a frequency of a synthesized clock. The DPFS method allows programmable phase modifications which are defined below:
phase increases of the synthesized clock are provided by adding a single gate delay or multiple gate delays to a present delay obtained from a propagation circuit of a reference clock;
phase decreases of the synthesized clock are provided by removing a single gate delay or multiple gate delays from a present delay obtained from the reference propagation circuit.

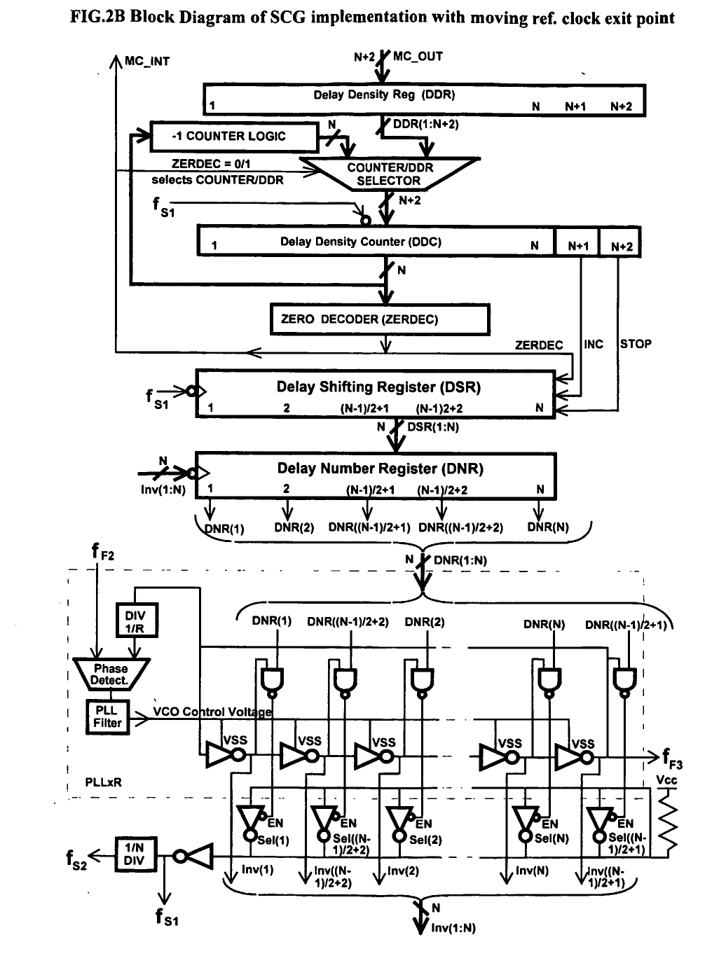

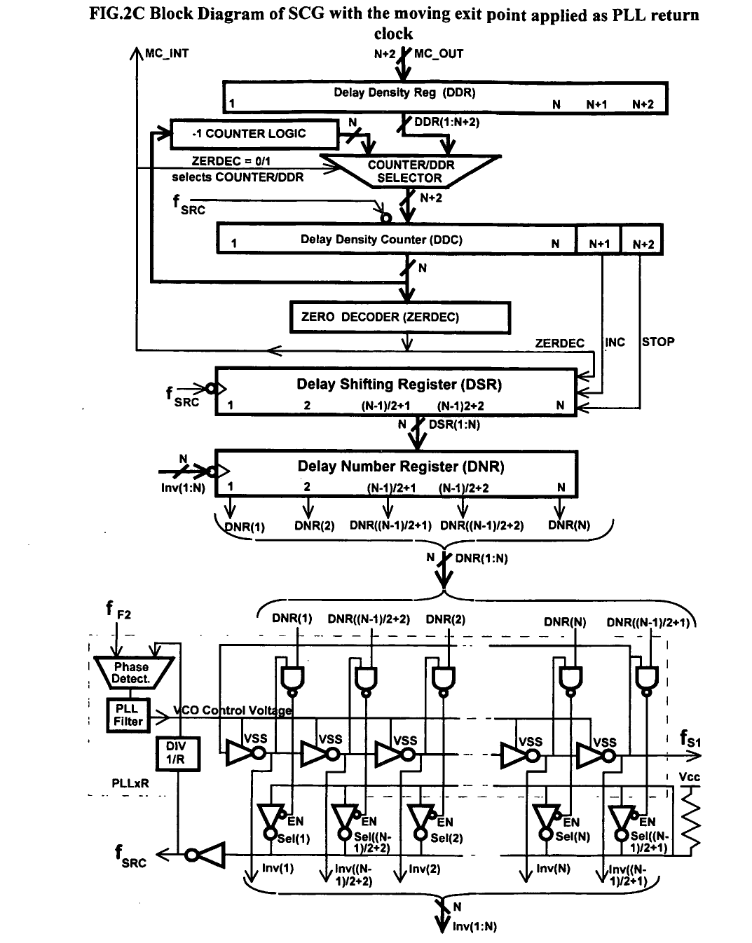

The DPFS method produces similar waveforms as commonly used DDFS method, but DPFS inserts single gates delays into pulses stream instead of eliminating the whole clock cycles from a synthesized clock. Therefore, the phase hits and resulting jitter are reduced by 10 times compared to the DDFS method. The DPFS method allows producing any f_{S1} clock waveform by using phase steps which are in a range of a gate propagation delay. The gate delays insertions and resulting phase/frequency adjustments can performed by a synthesized clock generator (SCG) which is introduced in FIG. 2A.

Synthesized Clock Generator (SCG)

The invention also includes the synthesized clock generator (SCG), for carrying out the DPFS method to produce the waveforms which are shown in FIG. 1. The SCG invention comprises 3 different SCG implementation methods, which are explained below.

The first SCG implementation method is based on moving reference clock entry point; wherein:
said phase increases are provided by moving an entry point of the reference clock into the reference propagation circuit, in a way which adds gate delays to a present delay obtained from the reference propagation circuit;
said phase decreases are provided by moving an entry point of the reference clock into the reference propagation circuit, in a way which subtracts gate delays from a present delay obtained from the reference propagation circuit.

The first SCG implementation method is conceptually presented in FIG. 2A, and its principles of operations are explained below.

The delays density register (DDR) defines a number of f_{F3} cycles which occur between consecutive increments or decrements of a phase of f_{F2} clock by a single gate delay time T_{d}.

The delays capture register (DCR) allows capturing a waveform which contains whole f_{F3} cycle. The delay calibration circuits (DCC) allow an estimation of an average T_{d}, and provide measurements of the captured f_{F3} positioning along the delay line.

Based on the f_{F3} positioning measurements, it shall be detected periodically that total delay line propagation time amounts to T_{TOTAL}=T_{d1}+T_{d2}+ . . . +T_{N}=T_{period} of f_{F3} In such cases amount of active delay elements is scaled down without changing the phase of the f_{S1} clock, by jumping an entry point of f_{F3} closer to the end of the delay line by a number of delay elements which corresponds to a period of the f_{F3} clock.

The second SCG implementation method is based on moving an exit point of the synthesized clock from the reference propagation circuit; in a way which adds gate delays for phase increases, and subtracts gate delays for phase decreases.

The second SCG implementation method is conceptually presented in FIG. 2B, and a way of carrying it out is explained below:
Chain of inverters from Inv(1) to Inv(N) which exists in the PLLxR frequency multiplier, can be utilized as the reference clock propagation circuit from which the synthesized clock f_{S1} can be selected as having gate delays added for phase increases or gate delays subtracted for phase decreases. The synthesized clock selection is performed by a currently active output of the delay number register (DNR(1:N)) which belongs to the delay increment/decrement circuit. As it is shown in the FIG. 2B;
any increase of DNR bit number by 1 adds 2 inverter delays to an actual phase of the f_{S1} clock, and any decrease of DNR bit number by 1 subtracts 2 inverter delays from an actual phase of the f_{S1} clock.

Said synthesized clock selection can be implemented in two different ways:
by using phase selecting gates from Sel(1) to Sel(N), as having 3state outputs with enable inputs EN enabled by the data number register outputs from DNR(1) to DNR(N) (see FIG. 2B);
or by using NAND gates having all their outputs connected into a common collector configuration (instead of the 3state gates), in order to allow a currently active DNR output to select a phase of the synthesized clock f_{S}.

The third SCG implementation method is based on adjusting alignment between an exit point of the synthesized clock from the reference propagation circuit versus an input reference clock; in a way which adds gate delays for phase increases, and subtracts gate delays for phase decreases.

The third method is presented in FIG. 2C, and its differences versus the FIG. 2B are explained below.

The moving exit point from the driven by f_{F2} phase locked delay line is used as a return clock for the PLLxR multiplier, instead of using fixed output of the Inv((N−1)/2+1) to be the PLL return clock.

The fixed output of the Inv((N−1)/2+1) provides the synthesized clock f_{S1}, instead of the moving reference clock exit point.

The exit point alignments introduce phase jumps which cause synthesized clock jitter. The configuration shown in FIG. 2C filters out jitter frequencies which are higher than a bandwidth of the multiplier's PLL.

While any of the three SCG implementation methods is shown above using a particular type of a reference clock propagation circuit, the SCG invention comprises using all the listed below reference clock propagation circuits by any of the three SCG methods:
an open ended delay line built with serially connected logical gates or other delay elements;
a ring oscillator built with serially connected logical gates or other delay elements, which have propagation delays controlled in a PLL configuration;
a delay line built with serially connected logical gates or other delay elements, which have propagation delays controlled in a Delay Locked Loop (DLL) configuration.
   Digital Phase Detector

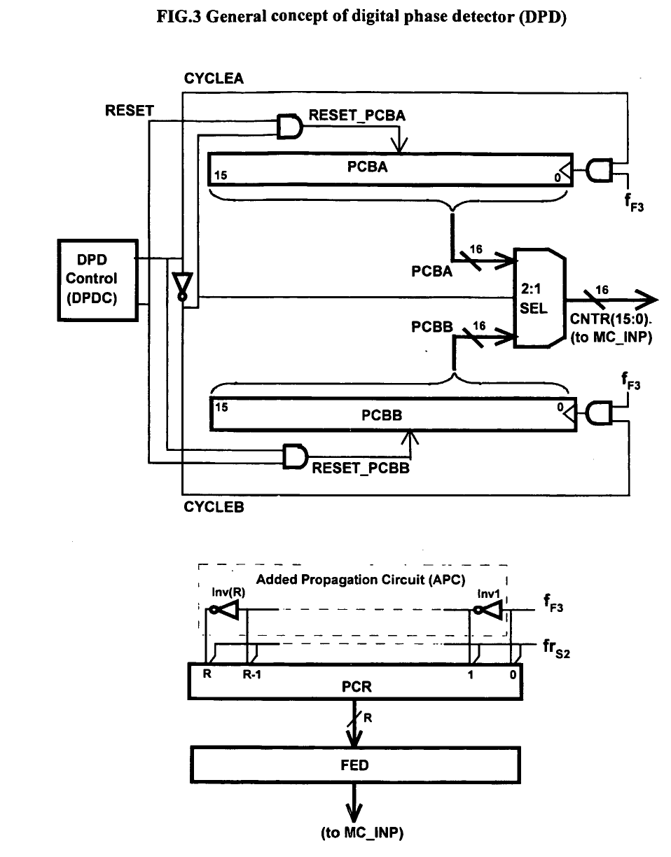

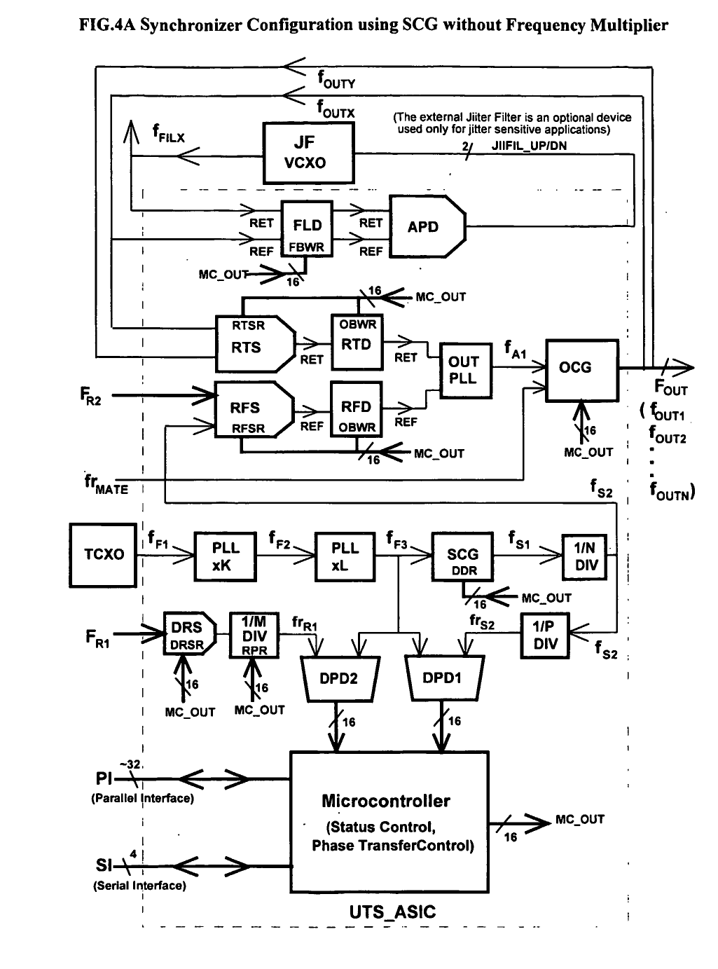

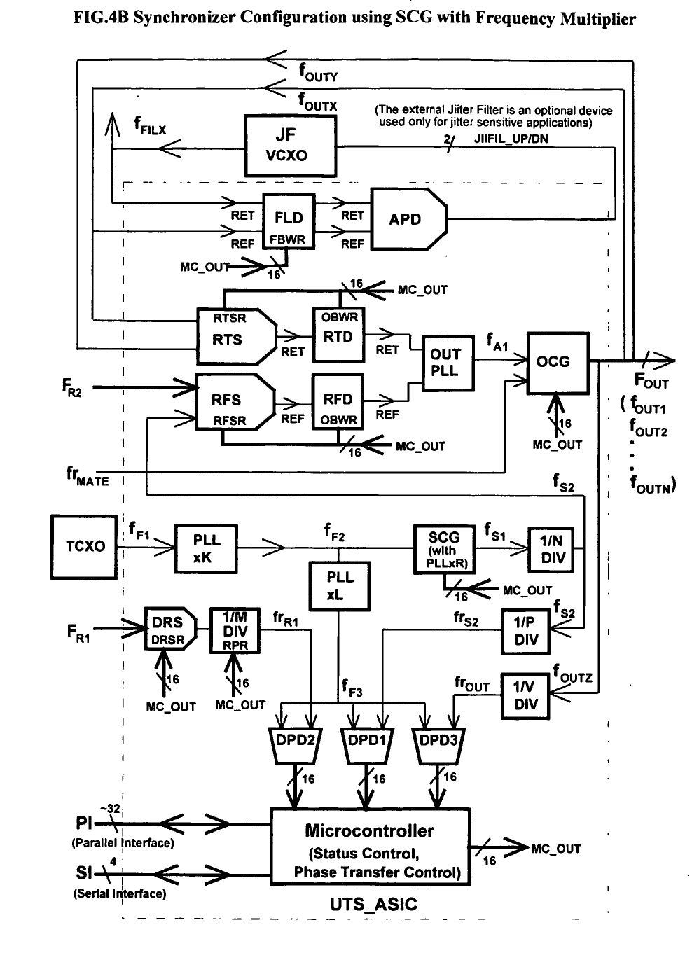

The invention also includes a new concept of a digital phase detector DPD 1 which is shown in FIG. 3. Whole UTS uses two DPDs: DPD1 and DPD2, in a configuration which is shown in FIG. 4. Since the DPD1 and DPD2 are identical, the FIG. 3 shows DPD1 connectivity only.

The DPD1 uses two symmetrical phase counters buffers A/B (PCBA/PCBB), which perform reverse functions during alternative A/B cycles of the frame clock fr_{S2} which is derived from the synchronized clock f_{S2}. During the A cycle, the PCBA counts the number of incoming f_{F3} clocks, but during the following B cycle the PCBA remains frozen until its content is read by the MC and subsequently the PCBA is reset before the beginning of the next A cycle. Alternatively, the PCBB performs counting during the B cycle and is read and reset during the following A cycle.

Such symmetrical PCBA/PCBB configuration allows much more time for counters propagation by inhibiting counting long before the actual reading takes place. Therefore, much higher frequencies of counted clocks are allowed for the same IC technology.

The above new concept of a digital phase detector, represents one of several possible DPD solutions; which are based on counting a first signal clock during every second signal frame, wherein the second signal frame contains a fixed number of the second signal clocks.

For all said DPD solutions, the invention further includes improving a DPD resolution by introducing a phase capture register. The phase capture register captures a state of outputs of multiple serially connected gates which the first signal clock is continuously propagated through, at the leading edge of the second signal frame.

Such resolution improvement is implemented in the DPD1, by using the phase capture register (PCR) to measure positioning of a last fr_{S2} edge versus f_{F3} waveform. The PCR and its frame edge decoder (FED), significantly improve phase detection resolution.

Said improvement of a DPD resolution further comprises two different solutions for obtaining the first clock propagation functionality:
adding the first clock propagation circuit specifically for providing input for the phase capture register; or utilizing a first clock propagation circuit which already inherently exists in a synchronization system.

The first mentioned solution is shown in the FIG. 3.

The second mentioned solution can be implemented as it is explained below. Instead of using the added propagation circuits (APC) from the FIG. 3; already existing in the system chain of inverters Inv(1) to Inv(N) from the FIG. 2B, can be utilized to measure the positioning of the last fr_{S2} edge versus f_{F3} waveform by capturing the outputs of all the inverters Inv(1) to Inv(N) in the phase capture register (PCR).

The second solution allows using shown in FIG. 2B single PLLxR for producing both the f_{F3} and the f_{S1} clocks, instead of using separate PLLxL and PLLxR as they are shown in FIG. 4A.

The second solution eliminates any need for delay calibration of the added propagation circuits (APC), because the replacing inverters Inv(1) to Inv(N) have their delays controlled very accurately by the VCO Control Voltage.

Integrated Synchronizer

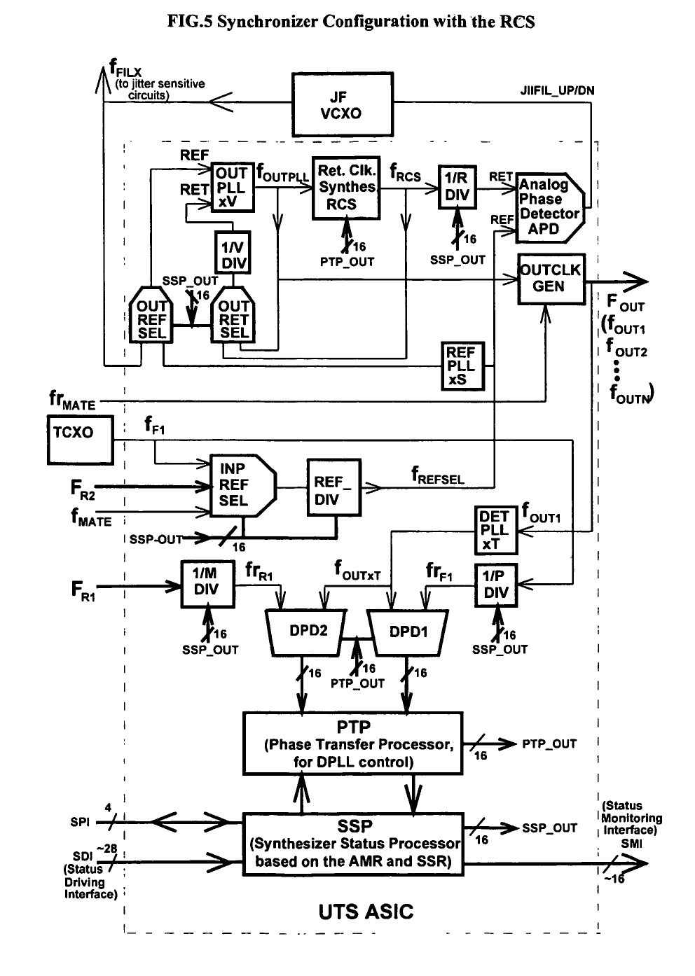

The invention further includes a synchronizer which is completely integrated into a single chip (see also FIG. 4A, FIG. 4B, FIG. 5). The integrated synchronizer comprises; a digital phase locked loop (DPLL) for locking an output clock to an incoming first reference signal, and an analog phase locked loop (APLL) for producing the output clock which can be locked to the first reference or to a second reference signal.

A first/second set of reference signals is named F_{R1}/F_{R2} and their single representatives are named f_{R1}/f_{R2} accordingly, throughout this document.

The synchronizer invention further comprises three different configurations which are explained below.

The first synchronizer configuration is based on the SCG which does not have an internal frequency multiplier (see FIG. 4A), and comprises circuits and functions which are listed below:
a synthesized clock generator (SCG) for generating a synthesized clock locked to a phase of the first reference signal;
a first digital phase detector (DPD1) for comparing a phase of the synthesized clock from said synthesized clock generator with a phase of a fixed reference clock, for producing a first phase error;
a second digital phase detector (DPD2) for comparing a phase of the first reference signal with the phase of the fixed reference clock, for producing a second phase error;
a microcontroller for driving said synthesized clock generator, based on the first phase error and the second phase error and in accordance with a preprogrammed phase transfer function (PTF);
the analog phase lock loop (APLL) for generating said synchronizer output clock; a programmable reference selector (RFS) for said APLL, for providing reference switching which allows the APLL to be driven by said synthesized clock or by one of multiple second reference signals F_{R2};
a programmable return clock selector (RTS) for said APLL, which allows implementing different synchronization schemes;
programmable frequency dividers for reference signals (RFD) and for return signals (RTD) of said APLL, for providing programmable bandwidth adjustments of the APLL;
a programmable DPLL reference selector (DRS) for selecting one of the multiple available reference signals F_{R1} for said DPLL, which allows switching between using different DPLL reference clocks;
programmable frequency dividers in the output clock generator (OCG) which can be reprogrammed by the MC, in order to allow utilizing a single pin of F_{OUT} for providing multiple different output clock frequencies;
activity monitoring circuits for synchronizer input clocks and output clocks;
frequency monitoring circuits for synchronizer reference clocks;
status control circuits for switching synchronizer modes of operation and active reference clocks, based on analysis of said activity and frequency monitoring circuits;
phase transfer control circuits for providing required phase transfer function between an active reference clock and synchronizer output clocks;
a serial interface which allows the status control circuits and the phase transfer control circuits to be monitored and reprogrammed by an external controller;
a parallel interface which allows the status control circuits and the phase transfer control circuits to be monitored and reprogrammed by an external controller;
automatic reference switching functions including hold-over and free-run switching, which are performed by the status control circuits and are based on monitoring a status of the activity and frequency monitoring circuits;
a master/slave switching circuit which allows a pair of integrated synchronizers to work in a master/slave configuration having a slave synchronizer being phase locked to a mate clock which is generated by a mate master synchronizer.
a re-timing circuit in the OCG which adjusts all the rising edges of the output clocks F_{OUT} of said slave synchronizer with the rising edge of the frame signal fr_{MATE} from said mate master synchronizer.

The above listed status control circuits and phase transfer control circuits can be implemented as separate on-chip microcontrollers or with a single on-chip microcontroller (MC).

The first synchronizer configuration is carried out by an UTS configuration which is based on the DPFS, the SCG, the DPD1 and the DPD2.

As it is shown in FIG. 4A, the first configuration allows the complete integration of the DPLL, the APLL, and all the other circuits and functions of the integrated synchronizer; into a single CMOS ASIC.

The on-chip implementation of a DPLL mode is explained below.

The DPD1 measures a phase error between TCXO's frequency multiplication f_{F3} and synthesized clock derivative fr_{S2}, and the DPD2 measures a phase error between the f_{F3} and the DPLL reference derivative f_{R1}.

The MC reads the above phase errors and uses them to calculate a new contents of SCG's delay density register (DDR), which shall fulfill a phase transfer function (PTF) which is preprogrammed on the MC input.

When UTS is working in the DPLL mode, the synthesized output clock f_{S2} is further applied as a reference for the on-chip APLL which is implemented with the programmable reference selector (RFS) and reference divider (RFD), output PLL (OUTPLL), output clock generator (OCG), programmable return selector (RTS) and return divider (RTD).

The on-chip implementation of an APLL mode uses an alternative reference clock f_{R2} as a reference for otherwise unchanged the above explained APLL; by selecting the f_{R2} on the RFS input, instead of the f_{S2} derivative of the SCG's output which would be selected for the DPLL mode.

It shall be noticed that the first synchronizer configuration uses lower frequency TCXO in order to reduce cost, and uses on-chip PLL cells to multiply TCXOs f_{F1} clock to a highest frequency which can be still feasible for a particular technology (see FIG. 4A). This multiplication reduces jitter as it is explained below.

Since the time period of the f_{F3} clock is reduced to a few nS by TCXO frequency multiplications; fewer delay elements are used for f_{S2} generation and power supply jitter introduced by the delay elements is proportionally decreased.

The invention further includes a simplified version of the first synchronizer configuration; which can be implemented by eliminating the first digital phase detector (DPD1), and by replacing it with calculations of the first phase error based on analysis of SCG control signals.

The invention of the first synchronizer configuration further includes a DPLL integrated synchronizer, which provides DPLL functions only. The DPLL integrated synchronizer can be obtained from the universal integrated synchronizer by eliminating the reference selector (RFS) and the programmable frequency dividers for reference and return signals of the APLL (RFD and RTD), by applying the f_{S2} signal directly to the OUTPLL reference input REF.

As it is shown in FIG. 4B, the second synchronizer configuration allows the complete integration of the DPLL, the APLL, and all the other circuits of the integrated synchronizer into a single CMOS ASIC.

The second synchronizer configuration comprises the same circuits and functions as the listed above for the first configuration, with the exceptions which are specified below.

Said second configuration uses an SCG which comprises a frequency multiplier PLLxR for producing a base frequency for the f_{S1} clock.

The internal SCG PLLxR multiplier provides a frequency increase which is sufficient for achieving a reasonable reduction of a physical size of the SCG. Consequently the single PLLxK frequency multiplier is sufficient to provide the SCG driving clock f_{F2}.

Still another PLLxL frequency multiplier is used with the multiplication factor L which is significantly different than the above mentioned factor R, in order to produce the f_{F3} clock. The f_{F3} drives digital phase detectors like the DPD1 and the DPD2, which represent extensive heavy loads which can introduce significant on-chip noise.

The above explained spacing between the f_{F3} versus the f_{S1} frequency reduces impact of inter-modulation products.

The third synchronizer configuration is based on the return clock synthesizer (RCS) (see the FIG. 5), and comprises the same circuits and functions as the listed above for the first configuration, with the exceptions which are specified below. The RCS can be implemented in identical way as any of the above described SCGs. Thus the RCS name indicates change in utilization only, while all the internal functions and circuits remain the same as in the SCG.

The third synchronizer configuration is carried out by an UTS configuration which is based on the DPFS, the RCS, and the DPD1 and DPD2.

As it is shown in FIG. 5, the third configuration allows the complete integration of the DPLL, the APLL, and all the other circuits of the integrated synchronizer into a single CMOS ASIC.

As it is further shown in FIG. 5, the Synthesizer Status Processor (SSP) is used to perform all status control functions and the Phase Transfer Processor (PTP) is designated to provide all the phase transfer processing and DPLL control functions.

Therefore the SSP and the PTP together represent the whole functionality of the MC as it has been defined above for the first and the second synchronizer configurations.

While this part of specification refers to the third synchronizer configuration, the invention includes using the above MC to SSP and PTP splitting for the first and for the second synchronizer configurations as well.

The on-chip implementation of a DPLL mode is explained below.

The SSP controls the input reference selector (INPREFSEL) and the reference divider (REF_DIV) which select and divide the TCXO's f_{OUT1} clock, in order to provide selected reference clock f_{REFSEL} which references the analog phase detector (APD) which drives the JF VCXO.

The JF VCXO provides low jitter clock f_{FILX}, which is applied as the reference clock for the output PLL (OUTPLL) via the output reference selector (OUTREFSEL).

The OUTPLL output f_{OUTPLL} is applied as the return clock for the OUTPLL via the output return selector (OUTRETSEL).

The OUTPLL supplies the f_{OUTPLL} clock for the OUTCLKGEN and the RCS.

The OUTCLKGEN provides the required set of output clocks F_{OUT}.

The RCS allows implementation of the phase synthesis process as it is explained below.

The RCS's output clock f_{RCS} is applied to 1/R divider which converts the f_{RCS} into a return clock for the APD.

The DPD1 measures a phase error between TCXO's frequency derivative fr_{F1} and the output clock multiplication f_{OUT\T}. The DPD2 measures a phase error between the DPLL reference derivative fr_{R1} and the output clock multiplication f_{OUT\T}.

The phase transfer processor (PTP) reads the above phase errors and uses them to calculate a new contents of RCS's delay density register (DDR), which shall fulfill a phase transfer function (PTF) which is preprogrammed on the PTP input.

The on-chip implementation of an APLL mode (see the FIG. 5) selects a derivative of the external clock f_{R2} to be the reference clock f_{REFSEL}. The f_{REFSEL} drives all the above described APD, JF VCXO, OUTPLL, RCS, OUTCLKGEN in the same configuration as described above for the DPLL mode. However during the APLL mode, the RCS remains frozen and never introduces any changes to a phase/frequency relation between the f_{RCS} clock versus the f_{OUTPLL} clock.

The invention includes providing slave mode implementation which replaces the external f_{R2} clock with the mate UTS output clock f_{MATE}, in order to drive the above described APLL configuration. The slave mode allows maintaining phase alignment between active and reserve UTS units, for the purpose of avoiding phase hits when protection switching reverts to using clocks from the reserve UTS unit.

While this part of specification refers to the third synchronizer configuration, the invention includes using the above mentioned method of slave UTS phase alignment for the first and for the second synchronizer configurations as well.

The invention further includes a simplified version of the third synchronizer configuration, which can eliminate the JF VCXO as it is described below.

The frequency of the f_{REFSEL} clock is multiplied by S by the reference PLL (REFPLL), and is selected with the output reference selector (OUTREFSEL) to provide the reference clock for the OUTPLL.

The RCS output f_{RCS} is selected by the output return selector (OUTRETSEL) to provide the return clock for the OUTPLL.

### DESCRIPTION OF THE PREFERRED EMBODIMENT

Synchronizer Configuration Based on SCG.

FIG. 4B shows UTS configuration according to the preferred embodiment. The UTS configuration integrates both Digital PLL (DPLL) and Analog PLL (APLL) into a single CMOS ASIC.

DPLL configurations are explained below.

TCXOs f_{F1} fixed output is multiplied by PLLxK cell and by PLLxL cell up to f_{F3} frequency which is used as a frequency reference by the digital phase detectors DPD1 and the DPD2.

Programmable 1/M divider (1/M DIV) allows the same input pin of the reference clock f_{R1} to be used for a variety of applications having different frequencies of DPLL reference clocks. The 1/M division ratio is programmed by MC_OUT contents being written into reference programming register (RPR).

The DPD1 measures a phase error between the synthesized clock fr_{S2} and the f_{F3} clock, as Δφ1=φ_fr_{S2}−φ_f_{F3}.

The DPD2 measures a phase error between a DPLL reference clock fr_{R1} and the f_{F3} clock, asΔφ2=φ_fr_{R1}−φ_f_{F3}.

Based on the measurements of Δφ1 and Δφ2, microcontroller (MC) calculates control codes for the delay density register (DDR) of the synthesized clock generator (SCG), which shall implement its preprogrammed transfer function between the synthesized clock and the DPLL reference clock.

While the synthesized clock f_{S2} is selected by the reference selector (RFS) and having the same frequency output clock f_{OUTY} is selected by the return selector (RTS), corresponding to them reference divider (RFD) and return divider (RTD) are set to the same division ratio (usually these dividers are set to 1) in order to drive output PLL (OUTPLL) and output clock generator (OCG).

For most configurations the output clocks set (F_{OUT}) is sufficient to drive all the system timing without any additional jitter filtering.

Only for some jitter sensitive applications, the output clock f_{OUTY} can be used as a reference for an external narrowband Jitter Filter PLL which is implemented with a bandwidth adjusting programmable filter divider (FLD), an Analog Phase Detector (APD) and an external jitter filter crystal oscillator JFVCXO. The FLD allows MC to reprogram the bandwidth of the Jitter Filter PLL for different type of applications and for different synchronization modes. Output of the JFVCXO is named f_{FILX}, and is available to be applied to a jitter sensitive circuit of a synchronized network element.

APLL implementations use analog portions of the above DPLL configurations, but the above described synthesized clock f_{S2} is not used as a reference for the output PLL (OUTPLL).

In the APLL mode, the reference selector RFS uses an alternative reference clock f_{R2} instead of the synthesized clock f_{S2}, as its reference clock.

The above mentioned reference and return selectors and dividers (RFS, RTS, RFD, RFD), allow diversified APLL configuring for a wide variety of applications and synchronization modes.

The DPD3 measures a phase error between an output clock f_{OUTZ} and the f_{F3} clock, asΔφ3=φ_f_{OUTZ}−φ_f_{F3}.

The Δφ3 measurements allow the synchronizer; to detect any “f_{OUTZ} out of range” condition, and to switch from the APLL mode to a “free-run mode” Additionally the Δφ3 and the Δφ1 measurements, allow the MC to work out SCG/DDR control codes which provide coherence of the f_{S2} signal versus the f_{OUTZ} signal. Therefore the invention allows switching from the APLL mode to a “hold-over mode”, by freezing the DDR content when activity monitor detects a failure of a presently used reference clock.

While this part of specification refers to the second synchronizer configuration: the invention includes using the above mentioned circuits and methods, of switching from the APLL mode to the free-run or the hold-over, for the first and for the third synchronizer configurations as well.

Similarly as for the DPLL, APLL may be configured with or without the jitter filter dependent of jitter levels requirements.

SCG Block Diagram and Circuits Description

The above mentioned third SCG implementation is selected for the preferred embodiment, and it is shown in the FIG. 2C and explained further below.

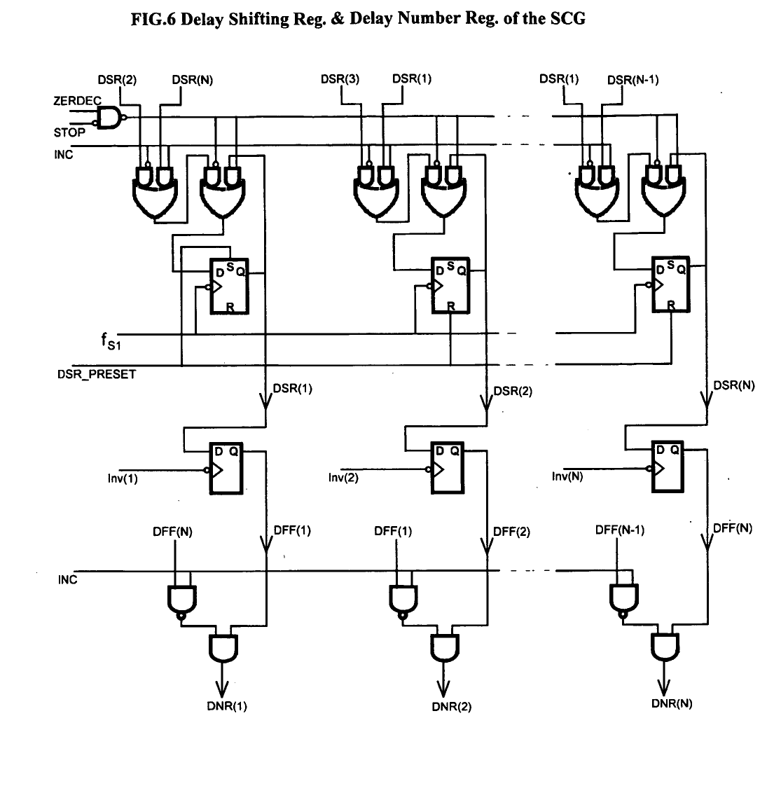

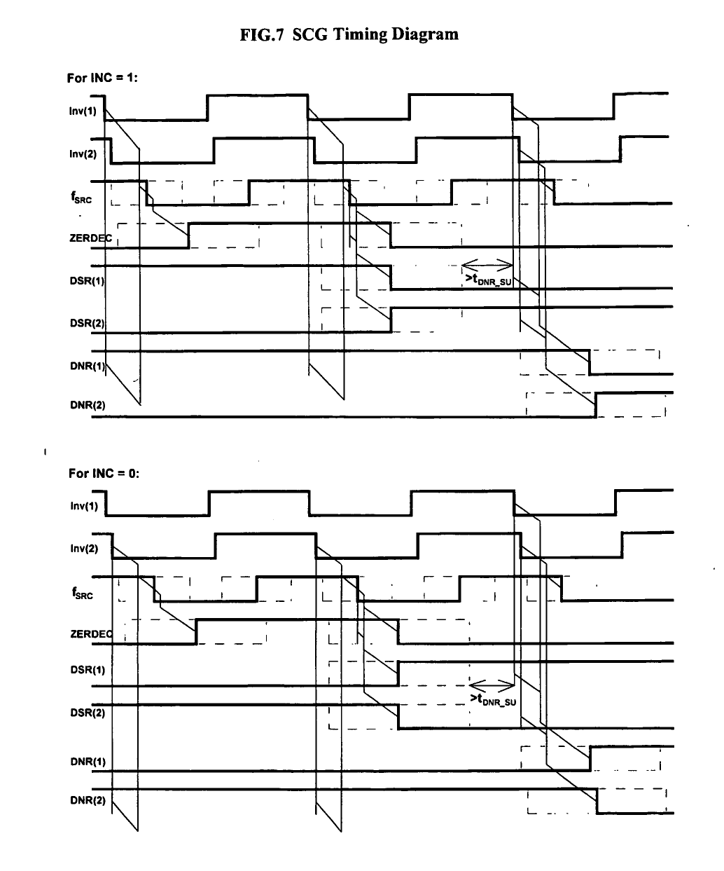

Details of the time critical Delay Shifting Register and the Delay Number Register are shown in FIG. 6 and detailed timing is shown in FIG. 7.

SCG selects outputs of the ring oscillator, based on the inverters Inv(1) to Inv(N), to be applied as PLL return clock f_{SRC}.

Moving the selected output forward by 2 inverters provides delayed f_{SRC} return clock; which causes the PLL to speed up the synthesized clock by the delay of the two inverters, in order to maintain phase locking between the f_{F2} and the f_{SRC} Using the return clock f_{SRC} instead of the synthesized clock f_{S1}, provides additional filtering of high frequency jitters in the f_{S1} by the PLL Filter.

Said oscillator output selection is made by a single active high output of the delay number register DNR(1:N).

The DNR bits are controlled by the delay flip-flops DFF(1:N) which are loaded from the delay shifting register DSR(1:N) by their corresponding outputs of the ring oscillator Inv(1) to Inv(N).

In the selector shown in the FIG. 2C, three state buffers are used to build the selector, but other configurations using open collector NAND gates can be used as well.

In order to eliminate any kind of glitches during the selection switching of the f_{SRC} clock; all the switching of a presently active DNR bit must be completed while selected oscillator output clocks remain in a low half-cycle condition.

During UTS power-up sequence, the DSR(1) bit is preset to 1 and all the other DSR(2:N) bits are reset.

Consequently, the delay shifting register DSR(1:N) always contains a single bit active high, while all the other bits are reset to 0.

DSR content is usually shifted right/left for INC=1/0, by a falling edge of the f_{SRC}; when zero content of the delay density counter DDC(1:N) is detected by the zero decoder (ZERDEC).

However said DSR shifting will not occur and DSR content remains frozen, if the STOP signal is set active high in the DDC.

The DDC(1:N) content is decreased by 1, by a falling edge of the f_{SRC}; when a non zero content of the delay density counter DDC(1:N) is detected by the zero decoder (ZERDEC).

The DDC(1:N+2) content is loaded with a content of the delay density register (DDR(1:N+2), by a falling edge of the f_{SRC}; when a zero content of the delay density counter DDC(1:N) is detected by the zero decoder (ZERDEC).

Additionally the ZERDEC=1 condition is signaled to the MC as the MC_INT, in order to allow more accurate phase control by MC phase transfer algorithms.

The DDR is loaded by the MC_OUT content, which is determined by MC phase transfer algorithms based on measurements provided by the digital phase detectors.

6.2 SCG Timing Analysis

The timing analysis is based on the timing diagrams which are shown in FIG. 7. The diagrams show; the f_{SRC}/f_{S1} phase increase/decrease for INC=1, and the f_{SRC}/f_{S1} phase decrease/increase for INC=0.

For INC=1 and ZERDEC=0:

The f_{SRC} keeps subtracting 1 from the content of the delay density counter (DDC), and the DNR(1) continues selecting the output of the Inv(1) to be the source of the f_{SRC}. For this stage the listed below timing requirements shall be fulfilled:

The propagation delay from f_{SRC} falling edge to eventual ZERDEC rising edge, must be lesser than f_{SRC} cycle minus DDC set-up time; where the ZERDEC propagation delay includes ZERDEC propagation through the COUNTER/DDR SELECTOR.

For INC=1 and ZERDEC=1:

When ZERDEC=1 is reached and signals that DDC content has been reduced to zero; the f_{SRC} falling edge shall load a content of the delay density register (DDR(1:N+2)) into the DDC(1:N+2), and the reloading of the DDC with a non zero content shall reset the ZERDEC signal.

Additionally, the f_{SRC} falling edge shall shift right the delay shifting register DSR, in order to deactivate the DSR(1) bit and to activate the DSR(2) bit. Consequently the next falling edge of the Inv(1) will reset the DNR(1) bit and the next falling edge of the Inv(2) will set the DNR(2) bit.

For this stage the listed below timing requirements shall be fulfilled.

The propagation delay from the F_{SRC} falling edge to eventual ZERDEC falling edge, must be lesser than the delay between the f_{SRC} falling edge cycle minus DDC set-up time; where the ZERDEC propagation delay includes ZERDEC propagation through the COUNTER/DDR SELECTOR.

The total propagation delay from the Inv(1) falling edge to the f_{SRC} falling edge plus from the f_{SRC} falling edge to the DSR(1)/DSR(2) falling/rising edge; must be lesser than the Inv(1) cycle minus DNR(1)/DNR(2) set up time.

It shall be noticed that for INC=1; every DFF output is inhibited from activating a corresponding DNR output, for as long as the previous DFF output is still active. Said inhibition prevents a premature activation of the next DNR bit, before the presently active DNR bit is reset. However even without the inhibition, the premature activation might happen only for extremely fast selector and DSR combined with extremely slow oscillator inverters.

For INC=0 and ZERDEC=0:

The f_{SRC} keeps subtracting 1 from the content of the delay density counter (DDC), and the DNR(2) continues selecting the output of the Inv(2) to be the source of the f_{SRC}. For this stage the listed below timing requirements shall be fulfilled.

The propagation delay from f_{SRC} falling edge to eventual ZERDEC rising edge; must be lesser than f_{SRC} cycle minus DDC set-up time; where the ZERDEC propagation delay includes ZERDEC propagation through the COUNTER/DDR SELECTOR.

For INC=0 and ZERDEC=1:

When ZERDEC=1 is reached and signals that DDC content has been reduced to zero; the f_{SRC} falling edge shall load a content of the delay density register (DDR(1:N+2)) into the DDC(1:N+2), and the reloading of the DDC with a non zero content shall reset the ZERDEC signal.

Additionally, the f_{SRC} falling edge shall shift left the delay shifting register DSR, in order to activate the DSR(1) bit and to deactivate the DSR(2) bit. Consequently the next falling edge of the Inv(1) will set the DNR(1) bit and the next falling edge of the Inv(2) will reset the DNR(2) bit. For this stage the listed below timing requirements shall be fulfilled:

The prop. delay from the f_{SRC} falling edge to eventual ZERDEC falling edge; must be lesser than the delay between the f_{SRC} falling edge cycle minus DDC set-up time; where the ZERDEC propagation delay includes ZERDEC propagation through the COUNTER/DDR SELECTOR.

The total propagation delay from the Inv(2) falling edge to the f_{SRC} falling edge plus from the f_{SRC} falling edge to the DSR(2)/DSR(1) falling/rising edge, must be lesser than the Inv(2) falling edge to the Inv(1) falling edge minus DNR(2)/DNR(1) set up time.

Digital Phase Detectors (DPD1/DPD2)

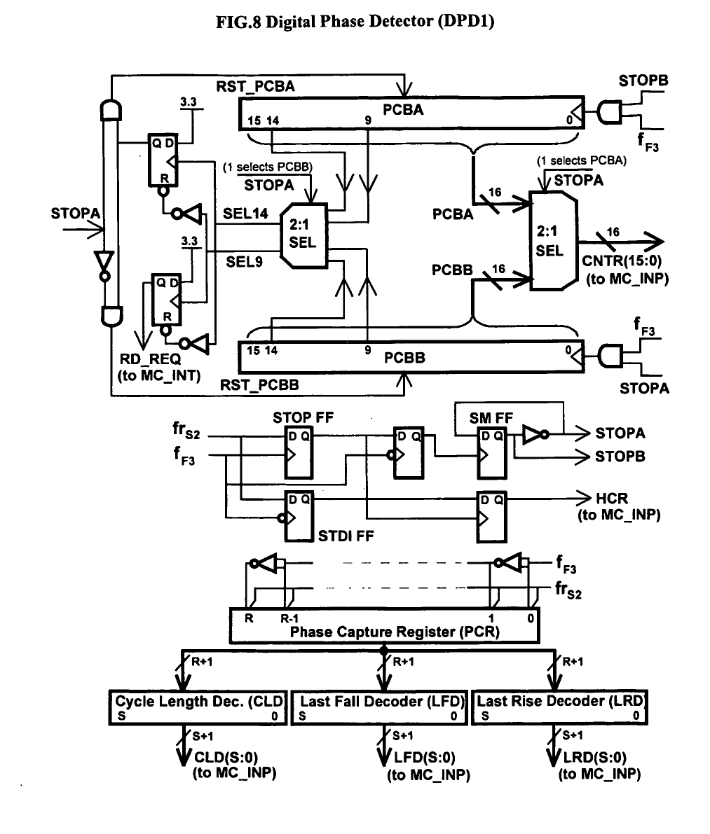

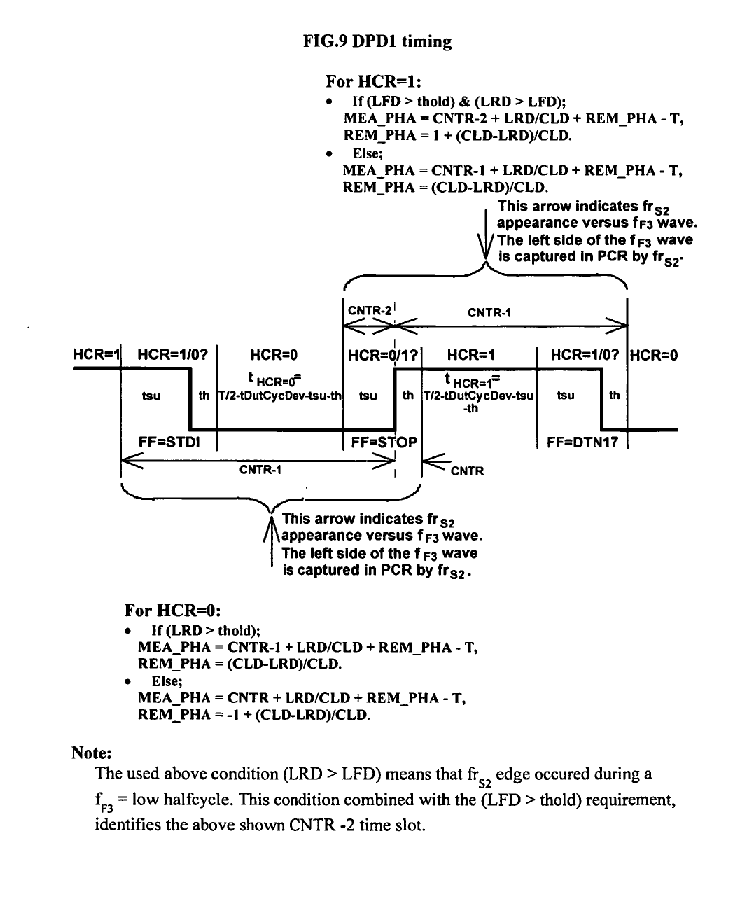

Since both digital phase detectors are identical, only DPD1 is described below, based on its presentation in FIG. 8 and FIG. 9.

Two major digital phase detector circuits are explained below.

A symmetrical twin pair PCBA/PCBB configuration allows higher counting speeds by eliminating all problems related to counters propagation delays.

The PCBA/PCBB configuration allows measurements of fr_{S2} versus f_{F3} phase errors, with a resolution of a single f_{F3} period.

When an fr_{S2} rise signals the end of the current phase measurement in a currently active phase counter (PCBA or PCBB), counting of f_{F3} clock is inhibited and the phase counter content remains frozen, until the next rise of the fr_{S2} signal when the counted clock will be enabled again. The whole fr_{S2} cycle is a very long freeze period, which is more than sufficient to accommodate; any kind of counter propagation, and the counter transfer to phase processing MC, and the counter reset. During the freeze period a mate phase counter is kept enabled and provides measurement of fr_{S2} phase.

Phase Capture Register (PCR) and its control and detection enhance phase detection resolution to a single inverter delay (i.e. by 10 times compared with conventional methods based on clock counting). This enhanced phase resolution is achieved by capturing f_{F3} propagation over inverters chain with a rising edge of fr_{S2} in the PCR, which is later decoded and transferred to the microcontroller (MC).

More detailed operations of the PCBA/PCBB configuration for both alternatives STOPA=1 and STOPB=1, are explained below.

When STOPA signal is active, DPD circuits perform listed below functions.

PCBB counts all rising edges of f_{F3} clocks.

PCBB generates SEL9 signal (when PCBB(9) goes high), which activates RD_REQ which initiates MC to read PCBA via CNTR(15:0).

MC calculates previous fr_{S2} versus f_{f3} phase error, by subtracting from the newly read PCB, the number T of f_{F3} clocks which nominally should correspond to the frame fr_{S2} (as it is shown in the FIG. 4, T=N×P).

PCBB generates SEL14 signal (when CTRB(14) goes high), which activates RST_PCBA which initiates PCBA reset circuits after its content has been read by MC.

When fr_{S2} rise occurs, STOP signal is activated and inverts STOPA/STOPB signals.

When STOPB signal is active all the above functionality is fulfilled with reversed roles of STOPB&PCBA versus STOPA&PCBB.

Detailed timing analysis of the enhanced phase capture circuits is shown in FIG. 9 and is explained below.

High Clock Region (HCR) signal shall be interpreted as it is defined below.

The HCR is set to 1: if f_{F3—}rise at fr_{S2}=high is detected by the STOP FF, after f_{F3—}fall at fr_{S2}=high was detected by the STDI FF (see FIG. 8). Therefore HCR=1 signals that fr_{S2} rising edge occurred in or around the f_{F3}=high halfcycle, as it is shown in the FIG. 9.

The HCR is reset to 0: if f_{F3—}rise at fr_{S2}=high is detected by the STOP FF, before f_{F3—}fall at fr_{S2}=high is detected by the STDI FF (see FIG. 8). Therefore HCR=0 signals that fr_{S2} rising edge occurred in or around the f_{F3}=low halfcycle; as it is shown in the FIG. 9.

PCR decoders are used for enhancing a phase detection resolution, and they are defined below.

Last Rise Decoder (LRD) provides a binary encoded position of f_{F3} rising edge, which has been captured at the most right location of the PCR.

Last Fall Decoder (LFD) provides a binary encoded position of f_{F3} falling edge, which has been captured at the most right location of the PCR.

Cycle Length Decoder (CLD) provides a binary encoded lengths of the f_{F3} wave, which has been captured between these 2 falling or 2 rising edges of the f_{F3} wave which occurred at the most right locations of the PCR.

MC algorithms for HCR, LRD, LFD and CLD interpretation are shown in FIG. 9, and use additional terms which are explained below.

Calculated by MC measured_phase (MEA_PHA) represents an actual phase error between fr_{S2} versus the equivalent f_{F3} frame; and consists of the listed below components.

CNTR-1/CNTR/CNTR-2 is an invalidated contents of a counter value CNTR which has been read by MC (all the invalidation algorithms are detailed in FIG. 9). LRD/CLD is a normalized value of a phase error between fr_{S2} rise versus last f_{F3} rise, as it has been read by MC from the LRD and CLD decoders.

Remaining_phase (REM_PHA) is calculated based on present measurement results, but MC stores and uses it to the correct next measurement result (all the REM_PHA calculation algorithms are shown in FIG. 9).

−T=−N×P (see FIG. 4 and FIG. 9); transforms a captured number of f_{F3} cycles per fr_{S2} period, into a phase error between fr_{S2} versus the equivalent f_{F3} based frame.

It shall be noted that in most cases a first f_{F3} rise which occurs after fr_{S2} rise, will set STOP FF=1 and freeze the previously active counter by inverting STOPA/STOPB signals. Since the first f_{F3} rise will still add 1 to the previously active counter; MC shall subtract 1 from the counter it reads, while a newly activated mate counter will begin with a correct 0 value. Therefore the first component of a calculated by MC MEA_PHA shall be CNTR-1.

When fr_{S2} rise occurs during t_{SU} of the STOP FF and HCR=1 (see the region “CNTR-2” in FIG. 9); the second f_{F3} rise will set STOP=1 and freeze previously active counter by inverting STOPA/STOPB signals. Since the first and the second f_{f3} rise will still add 1 to the previously active counter; MC shall subtract 2 from the counter it reads, while a newly activated mate counter will begin with an incorrect −1 value. Therefore the first component of a calculated by MC MEA_PHA shall be CNTR-2, and the first component of a stored by MC REM_PHA shall be +1.

When fr_{S2} rise occurs during t₁, of the STOP FF and HCR=0 (see the region “CNTR” in FIG. 9); the last passed f rise has already set STOP=1 and has already frozen previously active counter by inverting STOPA/STOPB signals. Since the next f_{F3} rise will not add 1 to the previously active counter; MC does not need to modify the counter it reads, while a newly activated mate counter will begin with an incorrect +1 value. Therefore the first component of a calculated by MC MEA_PHA shall be CNTR, and the first component of a stored by MC REM_PHA shall be −1.

While the LRD/CLD represents normalized PCR captured extension of the CNTR(15:0) captured phase, and is added to MEA_PHA; the remaining phase error between the fr_{S2} and the next f_{F3} rise, amounts to (CLD-LRD)/CLD and it is added to the REM_PHA in order to modify next measurement's MEA_PHA.

1-78. (canceled)

71. A synthesized clock generator modifying a length of a reference propagation circuit, contained between an entry point of a local reference clock and an exit point of a synthesized clock, by programmable shifting of the entry point of the local reference clock into the reference propagation circuit for providing programmable frequency relations between the local reference clock and the synthesized clock, the synthesized clock generator comprising:
a delay control circuit connected to a micro-controller output (MC_OUT), wherein the delay control circuit produces control signals defining frequency and size of phase delay modifications of the synthesized clock versus the reference clock;
an input selector connected to the local reference clock and to the delay control circuit, wherein the input selector uses inputs from the delay control circuit for selecting one of multiple outputs of the input selector for passing the local reference clock out;
the reference propagation circuit implemented with multiple serially connected gates having inputs of said serially connected gates connected to said outputs of the input selector, wherein the local reference clock is propagated through a part of the reference propagation circuit contained between the selected output of the input selector and an output of the reference propagation circuit which provides the synthesized clock;
whereby a sequence of phase modifications supplied by the micro-controller output is converted into selections of corresponding phase delays versus the local reference clock which provide said programmable relations between the frequency of the synthesized clock versus the frequency of the local reference clock.

72. The circuit of claim 71, further comprising:
a feedback means incorporated in the delay control circuit for generating a feedback signal sent back to the micro-controller, wherein the feedback signal identifies time and frequency of phase modifications implemented into the synthesized clock;
whereby the feedback signal supplies the micro-controller with the data needed for achieving a phase transients control of the synthesized clock, wherein said phase transients control upgrades the synthesized clock generator to a phase synthesizer category from a frequency synthesizer category.

73. The circuit of claim 71 wherein the delay control circuit comprises a delay number register performing circular shift operations defined by the micro-controller output, the delay number register produces said control signals defining frequency and size of phase delay modifications of the synthesized clock versus the reference clock.

74. The circuit of claim 71 wherein the delay control circuit comprises a delay number register performing register shift operations defined by the micro-controller output, the delay number register produces said control signals defining frequency and size of phase delay modifications of the synthesized clock versus the reference clock.

75. The circuit of claim 74 using an open ended reference propagation circuit and equipped with means allowing jumping to an opposite end of the reference propagation circuit when said entry point of the local reference clock is crossing another end, further comprising:
a delay capture register connected to the reference propagation circuit and to the local reference clock, wherein the delay capture register captures a phase delay between the synthesized clock and the local reference clock;
a sequential controller circuit connected to the delay capture register, wherein the sequential controller circuit detects a one cycle phase difference between the synthesized clock versus the local reference clock and includes a phase cycle decoder (PCD) which defines a number of inputs of the reference propagation circuit which corresponds to the whole cycle of the local reference clock;
a cycle jump means connected to said phase cycle decoder and included into said delay number register, wherein said cycle jump means shifts the delay number register by a number of bit positions which are defined by the phase cycle decoder as corresponding to a one cycle delay of the local reference clock.

76. The circuit of claim 71 including means for capturing a phase delay of the synthesized clock versus the local reference clock and calculating said entry point based on said captured phase delay and on the micro-controller output, further comprising:
a delay capture register connected to the reference propagation circuit and to the local reference clock, wherein the delay capture register captures a phase delay between the synthesized clock and the local reference clock;
a sequential controller circuit connected to the delay capture register, wherein the sequential controller circuit provides an entry point modification defining a number of inputs of the reference propagation circuit which a selection of said entry point is modified by;
an entry modification means connected to said sequential controller circuit and included into said delay control circuit, wherein said entry modification means incorporates said entry point modification into a content of the control outputs of the delay control circuit wherein said incorporation shifts a selection of said entry point by a number of bit positions which is defined by the entry point modification.

77-81. (canceled)

82. A synthesized clock generator modifying a length of a reference propagation circuit, contained between an entry point of a local reference clock and an exit point of a synthesized clock, by programmable shifting of said exit point from the reference propagation circuit with phase steps matching resolution of gate delays of the reference propagation circuit for providing programmable frequency relations between the synthesized clock and the local reference clock, the synthesized clock generator comprising:
a delay number register connected to a micro-controller output (MC_OUT) and to the synthesized clock, wherein the micro-controller output defines a direction and a number of bit positions by which a circular shifting synchronized by the synthesized clock is performed by the delay number register producing outputs which control frequency and size of phase delay modifications of the synthesized clock versus the reference clock;
the reference propagation circuit implemented with multiple serially connected gates having an input of a first gate connected to the local reference clock, wherein outputs of said serially connected gates constitute outputs of the reference propagation circuit which provide variety of phase delays versus the local reference clock;
an output selector connected to the outputs of the reference propagation circuit and to the outputs of the delay number register, wherein the output selector uses inputs from the delay number register for selecting an output of the reference propagation circuit which is passed through into an output of the output selector which provides the synthesized clock;
whereby a sequence of phase modifications supplied by the micro-controller output is converted into multiple selections of corresponding phase delays which provide said programmable relations between the frequency of the synthesized clock versus the frequency of the local reference clock.

83. The circuit of claim 82, further comprising:
a feedback means incorporated in the delay number register for generating a feedback signal sent back to the micro-controller, wherein the feedback signal identifies time and frequency of phase modifications implemented into the synthesized clock;
whereby the feedback signal supplies the micro-controller with the data needed for achieving a phase transients control of the synthesized clock, wherein said phase transients control upgrades the synthesized clock generator to a phase synthesizer category from a frequency synthesizer category.

84. The circuit of claim 82, wherein said reference propagation circuit is implemented with a phase locked loop (PLL).

85. The circuit of claim 82, wherein said reference propagation circuit is implemented with a delay locked loop (DLL).

86. The circuit of claim 82, wherein said reference propagation circuit is implemented with an open ended delay line.

87. A synthesized clock generator modifying a length of a reference propagation circuit, contained between an entry point of a local reference clock and an exit point of a synthesized clock, by programmable shifting of said exit point with phase steps matching resolution of gate delays of the reference propagation circuit wherein said programmable shifting includes capturing a phase delay of the synthesized clock versus the local reference clock and combining such captured phase delay with a micro-controller output for calculating said exit point, the synthesized clock generator comprising:
a delay control circuit connected to the micro-controller output (MC_OUT) wherein the delay control circuit produces control signals defining frequency and size of phase delay modifications of the synthesized clock versus the reference clock, the delay control circuit also having a terminal for an exit modification signal;
the reference propagation circuit implemented with multiple serially connected gates having an input of a first gate connected to the local reference clock, wherein outputs of said serially connected gates constitute outputs of the reference propagation circuit which provide variety of phase delays versus the local reference clock;
an output selector connected to the outputs of the reference propagation circuit and to the outputs of the delay control circuit, wherein the output selector uses inputs from the delay control circuit for selecting an output of the reference propagation circuit which is passed through into an output of the output selector which provides the synthesized clock;
a delay capture register connected to the local reference clock and to the synthesized clock and to the reference propagation circuit, wherein the delay capture register captures a phase delay between the synthesized clock and the local reference clock;
a sequential controller circuit connected to the delay capture register, wherein the sequential controller circuit provides an exit modification signal defining a number of inputs of the reference propagation circuit which a selection of said exit point is modified by;
whereby the sequential controller circuit processes, phase modifications supplied by the micro-controller output combined with said captured phase delays of the synthesized clock, into multiple selections of required phase delays which provide said programmable relations between the frequency of the synthesized clock versus the frequency of the local reference clock.

88. The circuit of claim 87, further comprising:
a feedback means incorporated in the delay control circuit for generating a feedback signal sent back to the micro-controller, wherein the feedback signal identifies time and frequency of phase modifications implemented into the synthesized clock;
whereby the feedback signal supplies the micro-controller with the data needed for achieving a phase transients control of the synthesized clock, wherein said phase transients control capability upgrades the synthesized clock generator to a phase synthesizer category from a frequency synthesizer category.

89. The circuit of claim 87 wherein said reference propagation circuit is implemented with an open ended delay line.

90-93. (canceled)

94. A synthesized clock generator modifying a length of a reference propagation circuit, contained between an entry point of a local reference clock and an exit point of a synthesized clock, by programmable shifting of a phase alignment of the whole reference propagation circuit versus the local reference clock for providing programmable frequency relations between the local reference clock and the synthesized clock provided by a fixed output of the reference propagation circuit, the synthesized clock generator comprising:
a delay control circuit connected to a micro-controller output (MC_OUT) wherein the delay control circuit produces control signals defining frequency and size of phase delays modifications of the synthesized clock versus the reference clock, the delay control circuit also having a terminal for a delay measurement signal;
a reference propagation circuit comprising multiple serially connected gates which is connected to and driven by the local reference clock wherein outputs of said serially connected gates constitute outputs of the reference propagation circuit which provide variety of phase delays versus the synthesized clock provided by an output of the reference propagation circuit, the reference propagation circuit also having a terminal for the delay measurement signal;
a delay measurement circuit connected to the reference propagation circuit and to the delay control circuit wherein the delay measurement circuit produces the delay measurement signal defining phase alignment of a one selected output of the reference propagation circuit versus the local reference clock;
whereby since a sequence of phase modifications supplied by the micro-controller output is converted into corresponding modifications of a lengths of the reference propagation circuit contained between the synthesized clock and the selected propagation circuit output which is aligned with the local reference clock by the reference propagation circuit, resulting synthesized clock delays provide said programmable relations between the frequency of the synthesized clock versus the frequency of the local reference clock.

95. The circuit of claim 94, further comprising:
a feedback means incorporated in the delay control circuit for generating a feedback signal sent back to the micro-controller, wherein the feedback signal identifies time and frequency of phase modifications implemented into the synthesized clock;
whereby the feedback signal supplies the micro-controller with the data needed for achieving a phase transients control of the synthesized clock, wherein said phase transients control capability upgrades the synthesized clock generator to a phase synthesizer category from a frequency synthesizer category.

96. The circuit of claim 94, wherein:
the reference propagation circuit is built with multiple serially connected gates configured as a ring oscillator controlled by a PLL which is connected to and driven by the local reference clock wherein outputs of said serially connected gates constitute outputs of the reference propagation circuit which provide variety of phase delays versus the synthesized clock provided by a fixed output of the reference propagation circuit, the PLL also having a PLL return terminal which is connected to the delay measurement signal;
the delay measurement circuit is built as a return selector connected to the delay control register and to the outputs of the reference propagation circuit providing variety of phase delays versus the synthesized clock, wherein the return selector uses inputs from the delay control register for selecting an output of the reference propagation circuit which is passed through to a return selector output which provides the delay measurement signal connected to the PLL return terminal;
whereby since a sequence of phase modifications supplied by the micro-controller output is converted into corresponding modifications of a lengths of the reference propagation circuit contained between the propagation circuit output selected for the PLL return clock and the synthesized clock wherein a phase of the PLL return clock is locked to the phase of the driving PLL local reference clock, resulting synthesized clocks delays provide said programmable relations between the frequency of the synthesized clock versus the frequency of the local reference clock.

97. The circuit of claim 96, wherein: the delay control circuit comprises a delay number register performing circular shift operations defined by the micro-controller output, the delay number register produces said control signals defining frequency and size of phase delay modifications of the synthesized clock versus the reference clock.

111. An integrated synchronizer comprising a digital phase locked loop (DPLL), using a synthesized clock generator (SCG) modifying a length of the reference propagation circuit contained between an input from a local reference clock and an output producing the synthesized clock, for implementing a phase transfer function (PTF) defining relation between a phase of the synthesized clock versus a phase of a first reference clock, wherein the integrated synchronizer comprises:
a micro-controller (MC) programmed to implement the phase transfer function (PTF) wherein a micro-controller output drives operations of the synthesized clock generator (SCG), the micro-controller has a terminal for a first phase error;
the SCG connected to the micro-controller and to the local reference clock, the SCG comprises the reference propagation circuit connected to the local reference clock wherein the SCG adjusts phase delay of the synthesized clock by modifying a length of the reference propagation circuit contained between an input from the local reference clock and an output producing the synthesized clock being a synchronizer output clock;
a first digital phase detector receiving the first reference clock and the local reference clock or receiving the first reference clock and the synthesized clock, wherein the digital phase detector produces the first phase error connected back to the micro-controller;
wherein said micro-controller uses its internal micro-operations for implementing filter functions of said DPLL by processing said first phase error into the micro-controller output driving the SCG into producing the synthesized clock compliant with the phase transfer function defined by the PTF.

112. The circuit of claim 111 including reference selection means for alternative use of one of multiple connected reference clocks for producing the synchronizer output clock, the circuit of claim 111 further comprising:
a reference selector connected to the multiple reference clocks and controlled by the micro-controller, wherein the micro-controller selects one of the multiple reference clocks for being used for producing the synchronizer output clock;
activity monitors for the external reference clocks for producing active/non-active output signals connected to the micro-controller;
wherein the activity monitors output signals are read and processed by the microprocessor producing reference selection signals connected to the reference selectors.

113. The circuit of claim 111 including means supporting a VCXO jiitter filter for synchronizer applications which are extremely jitter sensitive, the circuit of claim 111 further comprising:
an analog phase detector (APD) having a reference input connected to the synchronizer output clock and having a return input connected to an output clock of the VCXO jitter filter, wherein an output of the APD is used to drive a remaining circuit of the VCXO jitter filter.

114. The circuit of claim 111, further comprising:
an output clock generator (OCG) connected to the synthesized clock, wherein the OCG produces a plurality of synchronizer output clocks (FOUT).

115. The circuit of claim 111, further comprising:
an output phase locked loop (OUT-PLL) referenced by the synthesized clock and producing a synchronizer output clock, wherein the OUT-PLL has a return input connected to the synchronizer output clock or to a frequency divider of the synchronizer output clock.

116. The circuit of claim 111, further comprising:
an output phase locked loop (OUT-PLL) referenced by the synthesized clock and producing a fundamental output clock, wherein the OUT-PLL has a return input connected to a synchronizer output clock;
an output clock generator (OCG) connected to the fundamental output clock, the OCG produces a plurality of synchronizer output clocks (F_{OUT}) wherein one of the synchronizer output clocks is connected back to the return input of the OUT_PLL.

117. The circuit of claim 111 including an analog phase locked loop mode (APLL mode) of operation using a second reference clock (f_{R2}) as an external reference source which the synchronizer output clock is phase locked to, the circuit of claim 111 further comprising:
a reference selector connected to the synthesized clock and to the second reference clock and controlled by the micro-controller, wherein the micro-controller selects the second reference clock for the APLL mode or the synthesized clock for the DPLL mode;
an output phase locked loop (OUT-PLL) having a reference input connected to an output of the reference selector, wherein the OUT-PLL has a return input connected to the synchronizer output clock or to a frequency divider of the synchronizer output clock.

118. The circuit of claim 117 additionally provisioned for providing a plurality of synchronizer output clocks (F_{OUT}) which maintain phase alignment with the second reference clock (f_{R2}), the circuit of claim 117 further comprising:
an output clock generator (OCG) connected to a fundamental output clock produced by the OUT-PLL, the OCG produces a plurality of phase aligned synchronizer output clocks (F_{OUT}) wherein one of the synchronizer output clocks is connected back to the return input of the OUT_PLL.

119. The circuit of claim 117 including means for accepting frequencies of the second reference clock different than a frequency of the synthesized clock, the circuit of claim 117 further comprising:
a return selector connected to a synchronizer output clock having the same frequency as the synthesized clock and to other synchronizer output clock having the same frequency as the second reference clock, the micro-controller selects such input of the return selector which matches the frequency of the synthesized clock for the DPLL mode or the frequency of the second reference clock for the APLL mode wherein an output of the return selector is connected to the return input of the OUT-PLL.

120. The circuit of claim 119, further comprising:
a reference divider (RFD) inserted between the reference selector and the reference input of the OUT-PLL, wherein the reference divider is controlled by the micro-controller output (MC-OUT);
a return divider (RTD) inserted between the return selector and the return input of the OUT-PLL, wherein the return divider is controlled by the micro-controller output (MC-OUT);
whereby by changing division ratios in the RFD and in the RTD the micro-controller adjusts the synchronizer for using different frequencies of said second reference clock, and furthermore said changes of the division ratios provide programmable modifications of a bandwidth of the OUT-PLL.

121. The circuit of claim 117 including reference selection means for alternative use of one of multiple connected reference clocks for producing the synchronizer output clock, the circuit of claim 117 further comprising:
a first reference selector providing the first reference clock f_{R1} selected from a first set of reference clocks, the first reference selector connected to the first set of reference clocks and controlled by the micro-controller, wherein the micro-controller selects one of the first set clocks for being used for producing the synchronizer output clock;
a second reference selector providing the second reference clock f_{R2} selected from a second set of reference clocks, the second reference selector connected to the second set of reference clocks and controlled by the micro-controller, wherein the micro-controller selects one of the second set clocks for being used for producing the synchronizer output clock;
activity monitors, for the first set reference clocks and for the second set reference clocks, for producing active/non-active output signals connected to the micro-controller;
wherein the activity monitors output signals are read and processed by the microprocessor producing reference selection signals connected to the first reference selector and to the second reference selector.

122. A synchronizer as claimed in claim 121, the synchronizer comprising:
interface circuits, for communication with an external control processor, connected to the external control processor and to the synchronizer micro-controller;
wherein the interface circuits and the micro-controller enable the external control processor to read information about statuses of the activity monitors and to select an external reference clock or the local reference clock for driving the synchronizer output clock.

123. A synchronizer as claimed in claim 122, wherein: the interface circuits and the micro-controller enable the external control processor to perform switching of mode of operation of the synchronizer between the APLL mode and the DPLL mode.

124. A synchronizer as claimed in claim 121, wherein: the micro-controller reads information about statuses of the activity monitors and selects an external reference clock or the local reference clock for driving the synchronizer output clock.

125. A synchronizer as claimed in claim 124, wherein: the micro-controller performs switching of mode of operation of the synchronizer between the APLL mode and the DPLL mode.

126. A synchronizer as claimed in claim 125 wherein the micro-controller performs a master/slave switching for maintaining phase alignment between a an active back-plane synchronizer unit and a backup synchronizer unit, the synchronizer comprising:
a master/slave subroutine reading activity monitor of a reference clock produced by a mate synchronizer unit and reading internal status of the own synchronizer unit;
wherein the master/slave subroutine performs switching to a master mode by selecting other reference clock than the mate's reference clock when the mate's reference clock is inactive or performs switching to a slave mode by selecting the mate's reference clock for driving the APLL mode operation when the mate's reference clock is detected active during a power-up initialization of the own synchronizer unit.

127. An integrated synchronizer comprising a digital phase locked loop (DPLL) using a synthesized clock generator (SCG) modifying a length of a reference propagation circuit contained between an input from a synchronizer output clock and an output producing the synthesized clock, wherein the SCG is placed in a return path of an analog phase locked loop (APLL) producing the synchronizer output clock implementing a required phase transfer function (PTF) between a phase of the synchronizer output clock versus a phase of a first reference clock, the integrated synchronizer comprising:
a micro-controller (MC) programmed to implement the phase transfer function (PTF) wherein a micro-controller output drives operations of the synthesized clock generator (SCG), the micro-controller has a terminal for a first phase error;
the SCG connected to the micro-controller and to the synchronizer output clock, the SCG adjusts phase delay of the synthesized clock by modifying a length of the reference propagation circuit contained between an input from the synchronizer output clock and an output which sources out the synthesized clock;
the APLL having a reference input connected to a local reference clock and having a return input connected to the synthesized clock, wherein an output of the APLL produces the synchronizer output clock;
a first digital phase detector receiving the first reference clock and the local reference clock or receiving the synthesized clock and the local reference clock or the synchronizer output clock and the local reference clock, wherein the digital phase detector produces the first phase error connected back to the micro-controller;
wherein said micro-controller uses its internal micro-operations for implementing filter functions of said DPLL by processing said first phase error into the micro-controller output driving the SCG synthesized clock into providing the APLL return signal maintaining the PTF between the synchronizer output signal versus the first reference clock.

128. The circuit of claim 127 including reference selection means for alternative use of one of multiple connected reference clocks for producing the synchronizer output clock, the circuit of claim 127 further comprising:
a reference selector connected to the multiple reference clocks and controlled by the micro-controller, wherein the micro-controller selects one of the multiple reference clocks for being used for producing the synchronizer output clock;
activity monitors for the external reference clocks for producing active/non-active output signals connected to the micro-controller;
wherein the activity monitors output signals are read and processed by the microprocessor producing reference selection signals connected to the reference selectors.

129. The circuit of claim 127 including means supporting a VCXO jiitter filter for synchronizer application which are extremely jitter sensitive, the circuit of claim 127 further comprising:
an analog phase detector (APD) having a reference input connected to the synchronizer output clock and having a return input connected to an output clock of the VCXO jitter filter, wherein an output of the APD is used to drive a remaining circuit of the VCXO jitter filter.

130. The circuit of claim 127, further comprising:
an output clock generator (OCG) connected to the APLL output clock, wherein the OCG produces a plurality of synchronizer output clocks (F_{OUT}).

131. The circuit of claim 127 including an analog phase locked loop mode (APLL mode) of operation using a second reference clock (f_{R2}) as an external reference source which the synchronizer output clock is phase locked to, the circuit of claim 127 further comprising:
a reference selector connected to the local reference clock and to the second reference clock (f_{R2}) and controlled by the micro-controller, wherein the micro-controller selects the f_{R2} for the APLL mode or the local reference clock for the DPLL mode;
wherein an output of the reference selector is connected to the reference input of the APLL.

132. The circuit of claim 131 additionally provisioned for providing a plurality of synchronizer output clocks (F_{OUT}) which maintain phase alignment with the APLL output clock, the circuit of claim 131 further comprising:
an output clock generator (OCG) connected to the APLL output clock, the OCG produces a plurality of phase aligned synchronizer output clocks (F_{OUT}) wherein one of the synchronizer output clocks is connected back to the SCG which produces the synthesized clock connected to the return input of the APLL.

133. The circuit of claim 131 including reference selection means for alternative use of one of multiple connected reference clocks for producing the synchronizer output clock, the circuit of claim 131 further comprising:
a first reference selector providing the first reference clock f_{R1} selected from a first set of reference clocks, the first reference selector connected to the first set of reference clocks and controlled by the micro-controller, wherein the micro-controller selects one of the first set clocks for being used for producing the synchronizer output clock;
a second reference selector providing the second reference clock f_{R2} selected from a second set of reference clocks, the second reference selector connected to the second set of reference clocks and controlled by the micro-controller, wherein the micro-controller selects one of the second set clocks for being used for producing the synchronizer output clock;
activity monitors, for the first set reference clocks and for the second set reference clocks, for producing active/non-active output signals connected to the micro-controller;
wherein the activity monitors output signals are read and processed by the microprocessor producing reference selection signals connected to the first reference selector and to the second reference selector.

134. A synchronizer as claimed in claim 133, the synchronizer comprising:
interface circuits, for communication with an external control processor, connected to the external control processor and to the synchronizer micro-controller;
wherein the interface circuits and the micro-controller enable the external control processor to read information about statuses of the activity monitors and to select an external reference clock or the local reference clock for driving the synchronizer output clock.

135. A synchronizer as claimed in claim 134, wherein: the interface circuits and the micro-controller enable the external control processor to perform switching of mode of operation of the synchronizer between the APLL mode and the DPLL mode.

136. A synchronizer as claimed in claim 133, wherein: the micro-controller reads information about statuses of the activity monitors and selects an external reference clock or the local reference clock for driving the synchronizer output clock.

137. A synchronizer as claimed in claim 136, wherein: the micro-controller performs switching of mode of operation of the synchronizer between the APLL mode and the DPLL mode.

138. A synchronizer as claimed in claim 137, wherein the micro-controller performs a master/slave switching for maintaining phase alignment between an active back-plane synchronizer unit and a backup synchronizer unit, the synchronizer comprising:
a master/slave subroutine reading activity monitor of a reference clock produced by a mate synchronizer unit and reading internal status of the own synchronizer unit;
wherein the master/slave subroutine performs switching to a master mode by selecting other reference clock than the mate's reference clock when the mate's reference clock is inactive or performs switching to a slave mode by selecting the mate's reference clock for driving the APLL mode operation when the mate's reference clock is detected active during a power-up initialization of the own synchronizer unit.
